(19) United States
(12) Patent Application Publication
(10) Pub. No.: US 2026/0130038 A1
(43) Pub. Date: May 7, 2026

(54) DISPLAY MODULE AND MANUFACTURING METHOD THEREFOR

(71) Applicant: Samsung Electronics Co., Ltd., Suwon-si (KR)

(72) Inventors: Sera KWON, Suwon-si (KR); Byunghoon LEE, Suwon-si (KR); Juseung LEE, Suwon-si (KR)

(21) Appl. No.: 19/436,200

(22) Filed: Dec. 30, 2025

Related U.S. Application Data
(63) Continuation of application No. PCT/KR2024/009251, filed on Jul. 2, 2024.

(30) Foreign Application Priority Data
Jul. 3, 2023 (KR) 10-2023-0085770
Aug. 28, 2023 (KR) 10-2023-0112939

(51) Int. Cl. H10H 29/85; H10H 29/01; H10H 29/24

(52) U.S. Cl. CPC H10H 29/857; H10H 29/0364; H10H 29/24

(57) ABSTRACT

A display module and a manufacturing method therefor are provided. The display module includes a substrate including a plurality of electrode pads, a first non-conductive adhesive member formed on a surface of the substrate and having a first curing temperature, a second non-conductive adhesive member formed on the first non-conductive adhesive member and having a second curing temperature, and a plurality of light emitting elements bonded to the plurality of electrode pads, wherein electrodes of the plurality of light emitting elements are respectively bonded to the plurality of electrode pads by sequentially passing through the second non-conductive adhesive member and the first non-conductive adhesive member, and wherein the second curing temperature is higher than the first curing temperature.

### CROSS-REFERENCE TO RELATED APPLICATION(S)

This application is a continuation application, claiming priority under 35 U.S. C. § 365(c), of an International application No. PCT/KR2024/009251, filed on Jul. 2, 2024, which is based on and claims the benefit of a Korean patent application number 10-2023-0085770, filed on Jul. 3, 2023, in the Korean Intellectual Property Office, and of a Korean patent application number 10-2023-0112939, filed on Aug. 28, 2023, in the Korean Intellectual Property Office, the disclosure of each of which is incorporated by reference herein in its entirety.

### BACKGROUND

### 1. Field

The disclosure relates to a display module including a substrate having a plurality of non-conductive adhesive members formed thereon, and a manufacturing method therefor.

### 2. Description of Related Art

Along with the development trends of high luminance, high resolution, and large size in display devices mounted on various electronic devices, there has recently been a growing demand for high efficiency and low power consumption. Accordingly, a technology has been developed in which Light Emitting Diodes (LEDs) emitting Red (R), Green (G), and Blue (B) light are directly mounted on a substrate to form a display panel.

The LEDs are widely used not only as light sources for lighting devices but also as light sources for various display devices in a wide range of electronic products such as televisions (TVs), mobile phones, Personal Computers (PCs), laptop computers, and Personal Digital Assistants (PDAs). In particular, micro LEDs with sizes of 100 μm or less have recently been developed. Compared to conventional LEDs, the micro LEDs exhibit faster response speed, lower power consumption, and higher luminance, and thus are regarded as light emitting elements for next-generation displays. Furthermore, research has been continuously conducted to improve manufacturing yield of such display devices.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a display module including a substrate having a plurality of non-conductive adhesive members formed thereon, and a manufacturing method therefor.

Additional aspects will be set forth in part in the description which follows and, in part, will be apparent from the description, or may be learned by practice of the presented embodiments.

In accordance with an aspect of the disclosure, a display device is provided. The display device includes a substrate including a plurality of electrode pads, a first non-conductive adhesive member formed on a surface of the substrate and having a first curing temperature, a second non-conductive adhesive member formed on the first non-conductive adhesive member and having a second curing temperature, and a plurality of light emitting elements bonded to the plurality of electrode pads, wherein electrodes of the plurality of light emitting elements are respectively bonded to the plurality of electrode pads by sequentially passing through the second non-conductive adhesive member and the first non-conductive adhesive member, and wherein the second curing temperature is higher than the first curing temperature.

In accordance with another aspect of the disclosure, a method of bonding a plurality of light emitting elements on a substrate of a display device is provided. The method includes forming a first non-conductive adhesive member having a first curing temperature on a substrate including a plurality of electrode pads, forming a second non-conductive adhesive member having a second curing temperature on the first non-conductive adhesive member, aligning a plurality of electrodes of the light emitting elements on the plurality of electrode pads, applying heat and pressure to the plurality of electrodes of the light emitting elements such that the plurality of electrodes of the light emitting elements pass through the second non-conductive adhesive member within a first temperature range, applying the heat and the pressure to the plurality of electrodes of the light emitting elements such that the plurality of electrodes of the light emitting elements are inserted into the first non-conductive adhesive member within a second temperature range and are brought into contact with the plurality of electrode pads, and applying the heat and the pressure to the plurality of electrodes of the light emitting elements after the plurality of electrodes of the light emitting elements have passed through the second non-conductive adhesive member, such that the plurality of electrodes of the light emitting elements are bonded to the plurality of electrode pads within the second non-conductive adhesive member, wherein the second curing temperature is higher than the first curing temperature.

In accordance with another aspect of the disclosure, one or more non-transitory computer-readable storage media storing one or more computer programs including computer-executable instructions that, when executed by one or more processors of an electronic device individually or collectively, cause the electronic device to perform operations are provided. The operations include forming a first non-conductive adhesive member having a first curing temperature on a substrate including a plurality of electrode pads, forming a second non-conductive adhesive member having a second curing temperature on the first non-conductive adhesive member, aligning a plurality of electrodes of the light emitting elements on the plurality of electrode pads, applying heat and pressure to the plurality of electrodes of the light emitting elements such that the plurality of electrodes of the light emitting elements pass through the second non-conductive adhesive member within a first temperature range, applying the heat and the pressure to the plurality of electrodes of the light emitting elements such that the plurality of electrodes of the light emitting elements are inserted into the first non-conductive adhesive member within a second temperature range and are brought into contact with the plurality of electrode pads, and applying the heat and the pressure to the plurality of electrodes of the light emitting elements after the plurality of electrodes of the light emitting elements have passed through the second non-conductive adhesive member, such that the plurality of electrodes of the light emitting elements are bonded to the plurality of electrode pads within the second non-conductive adhesive member, wherein the second curing temperature is higher than the first curing temperature.

Other aspects, advantages, and salient features of the disclosure will become apparent to those skilled in the art from the following detailed description, which, taken in conjunction with the annexed drawings, discloses various embodiments of the disclosure.

### DESCRIPTION OF THE DRAWINGS

The above and other aspects, features, and advantages of certain embodiments of the disclosure will be more apparent from the following description taken in conjunction with the accompanying drawings, in which:

FIG. 1 is a front view briefly illustrating a display module according to an embodiment of the disclosure;

FIG. 2 is a block diagram briefly illustrating a display module according to an embodiment of the disclosure;

FIG. 3 is a cross-sectional view illustrating a portion of a display module including a substrate to which a light emitting element is bonded, according to an embodiment of the disclosure;

FIG. 4 is a cross-sectional view illustrating a portion of a display module including a substrate on which a non-conductive adhesive member containing conductive particles is formed, according to an embodiment of the disclosure;

FIG. 5 is a cross-sectional view illustrating a portion of a display module including a substrate on which a non-conductive adhesive member containing conductive particles and a non-conductive adhesive member having a black color are formed, according to an embodiment of the disclosure;

FIG. 6 illustrates a process of manufacturing a display module by bonding a plurality of light emitting elements to a substrate having a plurality of non-conductive adhesive members formed thereon, according to an embodiment of the disclosure;

FIG. 7 illustrates an example of a substrate having three non-conductive adhesive members formed thereon, according to an embodiment of the disclosure; and

FIG. 8 illustrates an example of a substrate having three non-conductive adhesive member formed thereon, according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

In addition, the terms ‘1st’, ‘2nd’, or the like may be used to describe various components, but the components shall not be limited by these terms. The terms are used to distinguish one component from another.

Throughout the specification, when a part is mentioned to be “connected” to another part, this includes not only a case where it is “directly connected” but also a case where it is “electrically connected” thereto with other elements interposed therebetween. Also, when a part is mentioned to “include” a component, this does not mean that it excludes other components, but rather that it may further include other components, unless otherwise specified.

Phrases such as “in an embodiment” mentioned in various sections of the disclosure do not necessarily all refer to the same embodiment.

An embodiment of the disclosure may be represented by functional block configurations and various processing steps. Some or all of these functional blocks may be implemented as various hardware and/or software components which perform specific functions. For example, the functional blocks of the disclosure may be implemented by one or more microprocessors, or may be implemented by circuit configurations designed for specific functions. Further, for example, the functional blocks of the disclosure may be implemented as various programming or scripting languages. The functional blocks may also be implemented as algorithms executed on one or more processors. Furthermore, the disclosure may employ the prior art for electronic environment configurations, signal processing, and/or data processing. Terms such as “mechanism,” “element,” “means,” and “configuration” are used broadly herein, and are not limited to mechanical or physical configurations.

In addition, connecting lines or connecting members between components shown in the drawings are provided merely as examples of functional connections and/or physical or circuit connections. In actual devices, the connections between the components may be implemented by various alternative or additional functional, physical, or circuit connections.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

Hereinafter, the disclosure will be described in detail with reference to the accompanying drawings.

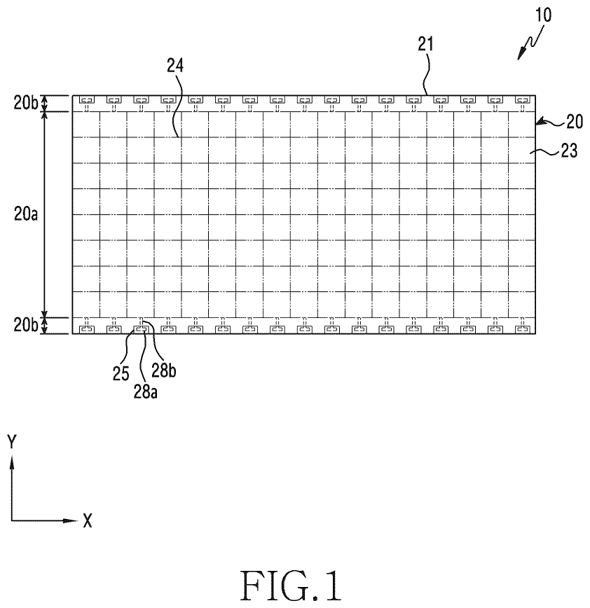

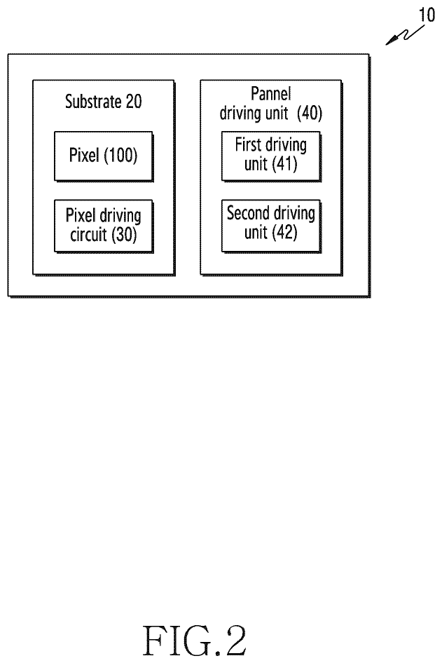

FIG. 1 is a front view briefly illustrating a display module according to an embodiment of the disclosure, and FIG. 2 is a block diagram briefly illustrating a display module according to an embodiment of the disclosure.

Referring to FIGS. 1 and 2, a display module 10 according to an embodiment of the disclosure may include a substrate 20 having a plurality of pixel driving circuits 30 formed thereon, a plurality of pixels 100 arranged on a front surface of the substrate 20, and a panel driving unit 40 configured to generate control signals and provide the generated control signals to the plurality of pixel driving circuits 30.

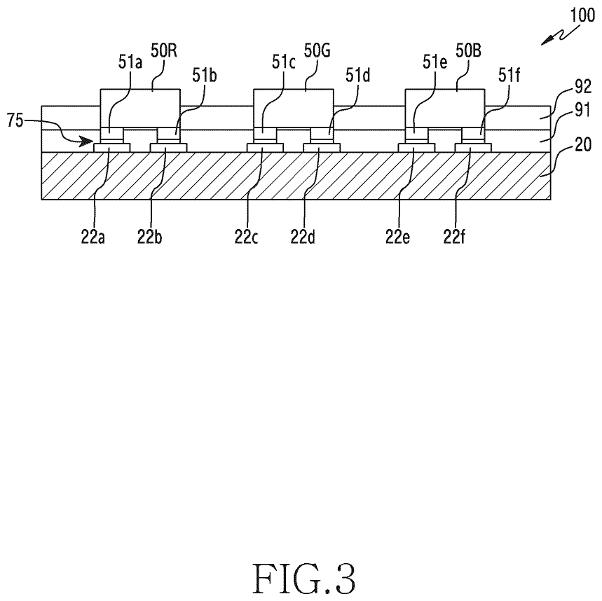

In the disclosure, one pixel 100 may include a plurality of sub-pixels. One sub-pixel may include one light source and a color conversion layer and a color filter, which correspond to each light source. Herein, the light source is an inorganic self-light emitting diode, and may be, for example, a Vertical Cavity Surface Emitting Laser (VCSEL) diode or micro Light Emitting Diode (micro LED) having a size of 100 μm or less (preferably 30 μm or less). The VCSEL diode and the micro LED may emit light of a blue wavelength band (450 to 490 nm) or ultraviolet wavelength band (360 to 410 nm). A structure of the pixel 100 will be described in detail below with reference to FIG. 3.

The substrate 20 may be a support base for attaching a plurality of electrical elements, for example, light emitting elements of a display, in an arranged manner. For example, the substrate 20 may be formed of any one of a glass material, a sapphire material, and a synthetic resin or ceramic material. For example, the substrate 20 may be a Thin Film Transistor (TFT) substrate. In this case, the substrate 20 may include a glass substrate 21, a TFT layer 23 including a TFT circuit on a front surface of the glass substrate 21, and a plurality of side wirings 25 which electrically couple the TFT circuit of the TFT layer 23 to circuits (not shown) disposed on a rear surface of the substrate 20. According to an embodiment, the substrate 20 may be formed of a rigid material or a flexible material.

The display module 10 may be formed using a synthetic resin-based substrate instead of the glass substrate 21. The synthetic resin-based substrate may be formed of, for example, PolyImide (PI), PolyEthylene Terephthalate (PET), PolyEtherSulfone (PES), PolyEthylene Naphthalate (PEN), or PolyCarbonate (PC). The synthetic resin-based substrate may have a flexible or rigid level of hardness.

Although not shown in the drawing, when the display module 10 is formed using the synthetic resin-based substrate instead of the glass substrate 21, a via hole may be formed in an active area 20a to be described later, and a wiring may be formed in the via hole. In this case, the front surface and rear surface of the substrate 20 may be electrically coupled to each other through the wiring formed in the via hole, and the plurality of side wirings 25 described above may be omitted from the substrate 20. In addition, an area (an inactive area 20b to be described later) in which a plurality of side wirings 25 are formed may be omitted from the substrate 20. When the inactive area 20b is omitted from the substrate 20 as described above, the active area 20a to be described later may be enlarged.

In addition, the display module 10 of the disclosure may be formed using a ceramic substrate instead of the glass substrate 21.

The substrate 20 may include the active area 20a, on which an image is displayable on the front surface thereof, and the inactive area 20b, on which the image is not displayable. The active area 20a may be divided into a plurality of pixel areas 24 on which a plurality of pixels are respectively arranged. The plurality of pixel areas 24 may be divided in various forms, and, for example, may be divided in a matrix form. One pixel area 24 may include one pixel 100 (see FIG. 3). The inactive area 20b may be included in an edge area of the glass substrate, and a plurality of connection pads 28a arranged at regular intervals along the edge area may be formed thereon. The plurality of connection pads 28a may be electrically coupled to the pixel driving circuits 30, respectively, through a wiring 28b.

The number of connection pads 28a formed on the inactive area 20b may vary depending on the number of pixels implemented on the substrate, and may also vary depending on a driving scheme of a TFT circuit arranged on the active area 20a. For example, an Active Matrix (AM) driving scheme which individually drives each pixel may require more wirings and connection pads than a Passive Matrix (PM) driving scheme in which the TFT circuit arranged on the active area 20a drives a plurality of pixels through horizontal and vertical lines.

In order to control the plurality of pixels 100, the TFT layer 23 may include a plurality of data signal lines arranged horizontally, a plurality of gate signal lines arranged vertically, and the plurality of pixel driving circuits 30 electrically coupled to the respective lines.

The TFT layer 23 may include, for example, a plurality of electrode pads 22a and 22b (see FIG. 3). The plurality of electrode pads 22a and 22b may be arranged in a predetermined number on each pixel area. For example, when three sub-pixels (e.g., first to third micro LEDs 50R, 50G, and 50B, see FIG. 3) are included in one pixel area, and each sub-pixel includes, for example, two electrodes 51a and 51b (see FIG. 3), six electrode pads 22a to 22f may be arranged on one pixel area. The micro LEDs 50R, 50G, and 50B may have a flip-chip structure in which anode and cathode electrodes are formed on the same first surface, and a light emitting surface is formed on a second surface opposite to the first surface.

TFTs constituting a TFT layer (or a backplane) are not limited to a specific structure or type. For example, the TFT cited in the disclosure may be implemented not only as a Low-Temperature Polycrystalline Silicon (LTPS) TFT but also as an oxide TFT, an Si TFT (such as poly silicon or a-silicon), an organic TFT, a graphene TFT, or the like. Only a P-type or N-type MOSFET may be formed and applied in a Si wafer CMOS process.

The panel driving unit 40 may be directly coupled to the substrate in a Chip on Glass (COG) or Chip on Plastic (COP) bonding manner, or may be indirectly coupled to the substrate 20 through a separate Flexible Printed Circuit Board (FPCB) in a Film on Glass (FOG) bonding manner. The panel driving unit 40 may drive the plurality of pixel driving circuits 30 to control light emission of a plurality of micro LEDs electrically coupled respectively to the plurality of pixel driving circuits 30.

The panel driving unit 40 may control the plurality of pixel driving circuits 30 line by line through a first driving unit 41 and a second driving unit 42. For example, the first driving unit 41 may generate control signals to sequentially control a plurality of horizontal lines formed on the TFT substrate 20 one line per video frame, and may transmit the generated control signals to the pixel driving circuits 30 respectively coupled to the corresponding lines. The second driving unit 42 may generate control signals to sequentially control a plurality of vertical lines formed on the TFT substrate 20 one line per video frame, and may transmit the generated control signals to the pixel driving circuits 30 respectively coupled to the corresponding lines.

In the disclosure, the display module may be a display panel having a micro light emitting diode which is a self-luminescence element for displaying images. For example, the display module may be a display panel, formed of a plurality of inorganic LEDs, each having a size of 100 micrometers or less, and may provide improved contrast, response time, and energy efficiency compared to a Liquid Crystal Display (LCD) panel which requires a backlight.

In the disclosure, the display module may be applied as a single unit by being installed in a wearable device, a portable device, a handheld device, and a variety of electronic products or automotive electronics requiring displays. The display module may also be applied to a display device such as a monitor for a Personal Computer (PC), a high-resolution television (TV), a signage (or a digital signage), and an electronic display through a plurality of assembly arrangements in a matrix type.

FIG. 3 is a cross-sectional view illustrating a portion of a display module including a substrate to which a light emitting element is bonded, according to an embodiment of the disclosure.

According to an embodiment, a plurality of pixel areas 24 (see FIG. 1) may be provided in a lattice form on a substrate 20 of a display module 10. One pixel 100 may be disposed to each of the pixel areas 24. The pixel 100 may include at least three sub-pixels (e.g., micro LEDs) which emit light with different colors.

Referring to FIG. 3, according to an embodiment, the pixel 100 may include a plurality of light emitting elements 50R, 50G, and 50B. For example, the plurality of light emitting elements 50R, 50G, and 50B may include a first micro LED 50R which emits light of a red wavelength band, a second micro LED 50G which emits light of a green wavelength band, and a third micro LED 50B which emits light of a blue wavelength band.

According to an embodiment, the plurality of light emitting elements 50R, 50G, and 50B may be electrically and physically coupled to the substrate 20 through a solder bump 75 formed at one end of each of electrodes 51a to 51f. For example, the first to third micro LEDs 50R, 50G, and 50B may be electrically and physically coupled to a TFT substrate through the solder bump 75. For example, the solder bump 75 may electrically and physically couple the first to third micro LEDs 50R, 50G, and 50B and the substrate 20. For example, the electrodes 51a and 51b of the first micro LED 50R may be electrically and physically coupled to corresponding electrode pads 22a and 22b of the substrate 20 through the solder bump 75. In this case, the electrode pads 22a and 22b of the substrate 20 may be arranged in a protruding shape or in a recessed shape on a surface of the substrate 20. Similarly, electrodes 51c, 51d, 51e, and 51f of the second and third micro LEDs 50G and 50B may be electrically and physically coupled to the corresponding electrode pads 22c, 22d, 22e, and 22f of the substrate 20 through the solder bump 75.

According to an embodiment, the solder bump 75 may be disposed between the electrodes 51a, 51b, 51c, 51d, 51e, and 51f of the light emitting elements 50R, 50G, and 50B and the electrode pads 22a, 22b, 22c, 22d, 22e, and 22f of the substrate 20. For example, the solder bump 75 may include a plurality of conductive particles. The conductive particles may be melted by heat (e.g., exceeding 150° C.) applied during a thermo-compression bonding process performed after transferring a plurality of micro LEDs onto the substrate 20, thereby forming a metal compound together with the electrodes 51a, 51b, 51c, 51d, 51e, and 51f and the electrode pads 22a, 22b, 22c, 22d, 22e, and 22f of the substrate 20. In this case, for example, the conductive particle may be a material capable of forming a metal compound with a chip electrode and a substrate electrode pad at a temperature of about 150° C. or lower, but the disclosure is not limited thereto. For example, the conductive particle may include at least one material selected from In, Sn, Bi, Cu, Ag, Au, Zn, Pd, Pb, and Ni.

According to an embodiment, the electrodes 51a, 51b, 51c, 51d, 51e, and 51f may include a filler layer and a barrier layer stacked thereon. The filler layer may reduce a contact resistance between a p-type semiconductor layer (or an n-type semiconductor layer) of the micro LED and the barrier layer, and may improve adhesion between the p-type semiconductor layer (or the n-type semiconductor layer) and the barrier layer. For example, the filler layer may be formed of at least one material selected from Au, Cu, Ni, and Al, but the disclosure is not limited thereto. For example, the barrier layer may be formed of at least one material selected from Au, Ni, Ti, Cr, Pd, TiN, Ta, TiW, TaN, AlSiTiN, NiTi, TiBN, ZrBN, TiAlN, and TiB2, but the disclosure is not limited thereto.

According to an embodiment, the electrode pads 22a, 22b, 22c, 22d, 22e, and 22f of the substrate 20 may be formed of at least one material selected from Au, Cu, Ag, Ni, Ni/Au, Au/Ni, Ni/Cu, and Cu/Ni, but the disclosure is not limited thereto.

According to an embodiment, the first to third micro LEDs 50R, 50G, and 50B may be physically fixed to the substrate 20 not only through the solder bump 75 but also through a plurality of cured non-conductive adhesive members 91 and 92.

According to an embodiment, the plurality of non-conductive adhesive members 91 and 92 may be formed on the substrate 20 before transferring the plurality of micro LEDs onto the substrate 20. For example, the plurality of non-conductive adhesive members 91 and 92 may be formed on the entire area of the front surface of the substrate 20. The plurality of non-conductive adhesive members 91 and 92 may be formed as multiple layers on the substrate 20. The plurality of non-conductive adhesive members 91 and 92 may further include a flux to facilitate bonding between the electrodes 51a, 51b, 51c, 51d, 51e, and 51f and the electrode pads 22a, 22b, 22c, 22d, 22e, and 22f by means of conductive particles.

According to an embodiment, the plurality of non-conductive adhesive members 91 and 92 may include the first non-conductive adhesive member 91 and the second non-conductive adhesive member 92. In this case, the first non-conductive adhesive member 91 may cover the electrode pads 22a and 22b and the solder bump 75 formed on the substrate electrode pad. In addition, the second non-conductive adhesive member 92 may be formed on the first non-conductive adhesive member 91.

According to an embodiment, the first non-conductive adhesive member 91 and the second non-conductive adhesive member 92 may be non-conductive films. The first non-conductive adhesive member 91 may be formed on the substrate 20 through a lamination process, and the second non-conductive adhesive member 92 may be formed on the first non-conductive adhesive member 91 through the lamination process. According to an embodiment, the first non-conductive adhesive member 91 and the second non-conductive adhesive member 92 may be transparent non-conductive films.

According to an embodiment, the first non-conductive adhesive member 91 may be formed of a material which is cured at a first curing temperature or higher, and the second non-conductive adhesive member 92 may be formed of a material which is cured at a second curing temperature or higher. The second curing temperature may be higher than the first curing temperature. The curing temperature may be a temperature at which curing of the material effectively begins. For example, the first non-conductive adhesive member 91 and the second non-conductive adhesive member 92 may have different curing temperatures, viscosities, and glass transition temperatures (Tg) by varying types and contents of components of the first and second non-conductive adhesive members 91 and 92. For example, the first non-conductive adhesive member 91 and the second non-conductive adhesive member 92 may have different curing temperatures, viscosities, and glass transition temperatures (Tg) by including different types and contents of at least one of additives, curing agents, fluxes, or epoxies.

According to an embodiment, the second non-conductive adhesive member 92 may be formed of a material having a higher viscosity than that of the first non-conductive adhesive member 91.

According to an embodiment, the light emitting elements 50R, 50G, and 50B transferred onto the substrate 20 may be brought into contact with the second non-conductive adhesive member 92 corresponding to an uppermost layer of the plurality of non-conductive adhesive members 91 and 92. For example, the plurality of micro LEDs 50R, 50G, and 50B may be brought into contact with the second non-conductive adhesive member 92. In this state, when the plurality of micro LEDs 50R, 50G, and 50B are thermo-compressed toward the substrate 20, the electrodes 51a, 51b, 51c, 51d, 51e, and 51f of the micro LEDs 50R, 50G, and 50B may be inserted into the second non-conductive adhesive member 92 and may pass through the second non-conductive adhesive member 92.

Thereafter, the electrodes 51a, 51b, 51c, 51d, 51e, and 51f of the plurality of micro LEDs 50R, 50G, and 50B may be inserted into the first non-conductive adhesive member 91 and bonded to the electrode pads 22a, 22b, 22c, 22d, 22e, and 22f in the first non-conductive adhesive member 91.

According to an embodiment, while the electrodes 51a, 51b, 51c, 51d, 51e, and 51f of the plurality of micro LEDs 50R, 50G, and 50B are inserted into the second non-conductive adhesive member 92 and the first non-conductive adhesive member 91 and are brought into contact with the electrode pads 22a, 22b, 22c, 22d, 22e, and 22f, since the viscosity of the second non-conductive adhesive member 92 is higher than that of the first non-conductive adhesive member 91, during a high-temperature, high-pressure bonding process, a film shape of the first non-conductive adhesive member 91 may be maintained, and flatness of the appearance of the display module 10 may be improved.

According to an embodiment, the first non-conductive adhesive member 91 and the second non-conductive adhesive member 92 may be cured by heat. Accordingly, the plurality of micro LEDs may be securely fixed to the substrate 20 by the cured first non-conductive adhesive member 91 and second non-conductive adhesive member 92 while being inserted into the first non-conductive adhesive members 91 and the second non-conductive adhesive member 92.

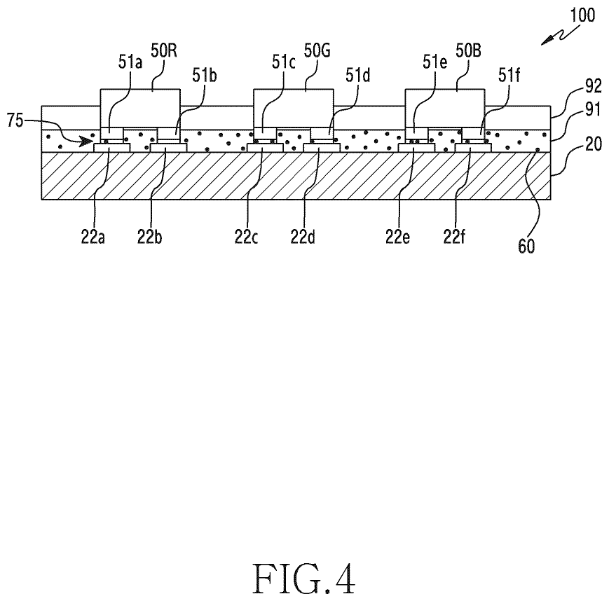

FIG. 4 is a cross-sectional view illustrating a portion of a display module including a substrate on which a non-conductive adhesive member containing conductive particles is formed, according to an embodiment of the disclosure.

Referring to FIG. 4, a first non-conductive adhesive member 91 according to an embodiment may include a plurality of conductive particles 60. The plurality of conductive particles 60 may be conductive powders, and may include, for example, at least one conductive material selected from Sn, Cu, Ni, In, Ag, Au, carbon, Co, Fe, Cr, Mo, Ti, Bi, Pd, Pb, and Ge. A density of the plurality of conductive particles 60 in the first non-conductive adhesive member 91 may be less than or equal to a predetermined value. Accordingly, the first non-conductive adhesive member 91 may maintain electrically non-conductive properties.

According to an embodiment, the first non-conductive adhesive member 91, which includes the plurality of conductive particles 60, may be formed on a lowermost layer of the plurality of non-conductive adhesive members 91 and 92. Accordingly, the conductive particles 60 may be melted by heat (e.g., exceeding 150° C.) applied during a thermo-compression bonding process, thereby forming a metal compound together with electrodes 51a, 51b, 51c, 51d, 51e, and 51f and substrate electrode pads 22a, 22b, 22c, 22d, 22e, and 22f.

According to an embodiment, the first non-conductive adhesive member 91 and the second non-conductive adhesive member 92 may be transparent non-conductive films.

Although it is described in FIG. 4 that the plurality of conductive particles 60 are included in the first non-conductive adhesive member 91, the disclosure is not limited thereto. The plurality of conductive particles 60 may also be included in another non-conductive adhesive member.

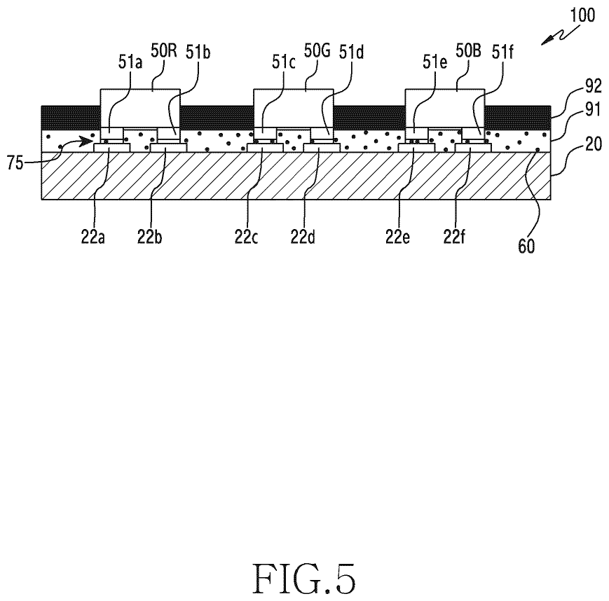

FIG. 5 is a cross-sectional view illustrating a portion of a display module including a substrate on which a non-conductive adhesive member containing conductive particles and a non-conductive adhesive member having a black color are formed, according to an embodiment of the disclosure.

Referring to FIG. 5, a second non-conductive adhesive member 92 according to an embodiment may have a black color. For example, the second non-conductive adhesive member 92 may be a black non-conductive film. The black second non-conductive adhesive member 92 may be formed on an uppermost layer of the plurality of non-conductive adhesive members 91 and 92, but the disclosure is not limited thereto.

When a plurality of micro LEDs 50R, 50G, and 50B are bonded to a substrate 20 on which the black second non-conductive adhesive member 92 is formed, an optical characteristic of a display module 10 may be improved. In addition, for example, by allowing only some of the plurality of non-conductive adhesive members 91 and 92 to have the black color, it is possible to improve the optical characteristic of the display module 10 while maintaining surface roughness.

Referring to FIG. 5, the first non-conductive adhesive member 91 according to an embodiment may include the plurality of conductive particles 60. The plurality of conductive particles 60 may be conductive powders, and may include, for example, at least one conductive material selected from Sn, Cu, Ni, In, Ag, Au, carbon, Co, Fe, Cr, and Mo. A density of the plurality of conductive particles 60 in the first non-conductive adhesive member 91 may be less than or equal to a predetermined value. Accordingly, the first non-conductive adhesive member 91 may maintain electrically non-conductive properties. The first non-conductive adhesive member 91 including the plurality of conductive particles 60 may be formed on a lowermost layer of the plurality of non-conductive adhesive members 91 and 92.

Although it is described in FIG. 5 that the second non-conductive adhesive member 92 has the black color, the disclosure is not limited thereto. For example, the first non-conductive adhesive member 91 including the plurality of conductive particles 60 may also have the black color.

Although it is described in FIG. 5 that the second non-conductive adhesive member 92 has the black color and the first non-conductive adhesive member 91 incudes the plurality of conductive particles 60, the disclosure is not limited thereto. For example, the second non-conductive adhesive member 92 may have the black color, and the first non-conductive adhesive member 91 may not include the plurality of conductive particles 60.

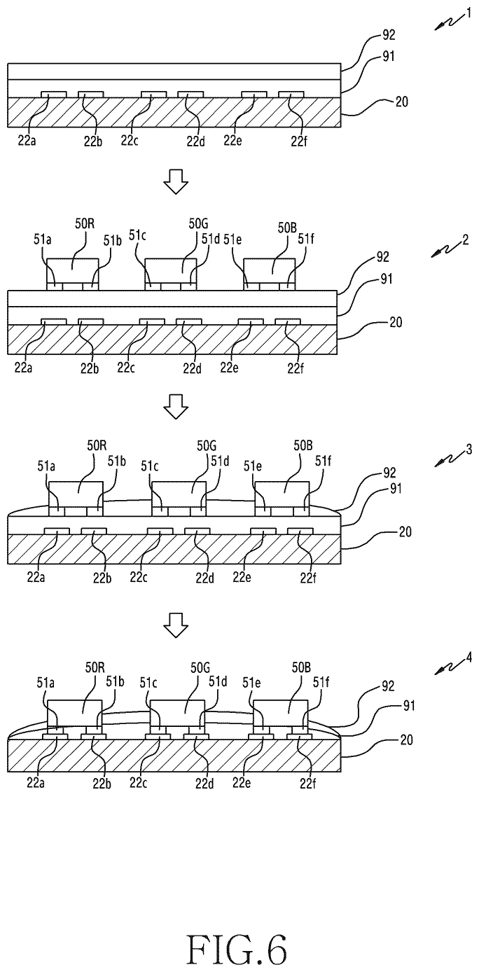

FIG. 6 illustrates a process of manufacturing a display module by bonding a plurality of light emitting elements to a substrate having a plurality of non-conductive adhesive members formed thereon, according to an embodiment of the disclosure.

The process of manufacturing the display module 10 of FIG. 6 may be used to manufacture the display module 10 of FIGS. 1 to 5.

Referring to a reference numeral 1 of FIG. 6, a plurality of non-conductive adhesive members 91 and 92 may be formed on a substrate 20. For example, the first non-conductive adhesive member 91 may be formed on the substrate 20, and the second non-conductive adhesive member 92 may be formed on the first non-conductive adhesive member 91. For example, the first non-conductive adhesive member 91 may be a non-conductive film having a first curing temperature, and the second non-conductive adhesive member 92 may be a non-conductive film having a second curing temperature. A second viscosity of the second non-conductive adhesive member 92 may be higher than a first viscosity of the first non-conductive adhesive member 91, and the second curing temperature may be higher than the first curing temperature. In addition, for example, the plurality of non-conductive adhesive members 91 and 92 may have a thickness of 1 to 10 μm, and may have heat-curable and/or UV-curable properties.

According to an embodiment, the first non-conductive adhesive member 91 may be attached on the substrate 20 through a lamination process, and the second non-conductive adhesive member 92 may be attached on the first non-conductive adhesive member 91 through the lamination process.

Referring to a reference numeral 2 of FIG. 6, a plurality of light emitting elements 50R, 50G, and 50B may be aligned on the substrate 20. For example, the plurality of micro LEDs 50R, 50G, and 50B may be aligned on the substrate 20 such that electrodes 51a, 51b, 51c, 51d, 51e, and 51f of the plurality of micro LEDs 50R, 50G, and 50B face electrode pads 22a, 22b, 22c, 22d, 22e, and 22f on the substrate 20. The plurality of micro LEDs 50R, 50G, and 50B aligned on the substrate 20 may be brought into contact with the second non-conductive adhesive member 92.

Referring to a reference numeral 3 of FIG. 6, the plurality of light emitting elements 50R, 50G, and 50B may be inserted into the second non-conductive adhesive member 92 by a high-temperature, high-pressure bonding process. For example, the electrodes 51a, 51b, 51c, 51d, 51e, and 51f of the plurality of micro LEDs 50R, 50G, and 50B may move within the second non-conductive adhesive member 92 to face the electrode pads 22a, 22b, 22c, 22d, 22e, and 22f on the substrate 20.

According to an embodiment, within a first temperature range, the electrodes 51a, 51b, 51c, 51d, 51e, and 51f of the plurality of micro LEDs 50R, 50G, and 50B may move within the second non-conductive adhesive member 92 toward the electrode pads 22a, 22b, 22c, 22d, 22e, and 22f. In this case, the first temperature range may be lower than the second curing temperature of the second non-conductive adhesive member 92. For example, heat at a temperature higher than the first curing temperature and the second curing temperature may be applied to the substrate 20 and/or the plurality of non-conductive adhesive members 91 and 92, and within the first temperature range before the temperature of the second non-conductive adhesive member 92 reaches the second curing temperature due to the applied heat, the electrodes 51a, 51b, 51c, 51d, 51e, and 51f of the plurality of micro LEDs 50R, 50G, and 50B may move within the second non-conductive adhesive member 92 toward the electrode pads 22a, 22b, 22c, 22d, 22e, and 22f.

Referring to a reference numeral 4 of FIG. 6, the plurality of light emitting elements 50R, 50G, and 50B which have passed through the second non-conductive adhesive member 92 by the high-temperature, high-pressure bonding process may be inserted into the first non-conductive adhesive member 91. For example, the electrodes 51a, 51b, 51c, 51d, 51e, and 51f of the plurality of micro LEDs 50R, 50G, and 50B may move within the first non-conductive adhesive member 91 toward the electrode pads 22a, 22b, 22c, 22d, 22e, and 22f on the substrate 20.

According to an embodiment, within a second temperature range, the electrodes 51a, 51b, 51c, 51d, 51e, and 51f of the plurality of micro LEDs 50R, 50G, and 50B may move within the first non-conductive adhesive member 91 toward the electrode pads 22a, 22b, 22c, 22d, 22e, and 22f. In this case, the second temperature range may be lower than the first curing temperature of the first non-conductive adhesive member 91. For example, heat at a temperature higher than the first curing temperature and the second curing temperature may be applied to the substrate 20 and/or the plurality of non-conductive adhesive members 91 and 92, and within the second temperature range before the temperature of the first non-conductive adhesive member 91 reaches the first curing temperature due to the applied heat, the electrodes 51a, 51b, 51c, 51d, 51e, and 51f of the plurality of micro LEDs 50R, 50G, and 50B may be in contact with the electrode pads 22a, 22b, 22c, 22d, 22e, and 22f or solder bumps on the electrode pads 22a, 22b, 22c, 22d, 22e, and 22f within the second non-conductive adhesive member 92.

According to an embodiment, a second curing temperature of the second non-conductive adhesive member 92 may be higher than a first curing temperature of the first non-conductive adhesive member 91, and a second viscosity of the second non-conductive adhesive member 92 may be higher than a first viscosity of the first non-conductive adhesive member 91. Accordingly, even if the first viscosity of the first non-conductive adhesive member 91 is low, since the second viscosity of the second non-conductive adhesive member 92 is high, the second non-conductive adhesive member 92 may maintain a shape thereof while the electrodes 51a, 51b, 51c, 51d, 51e, and 51f of the plurality of micro LEDs 50R, 50G, and 50B move within the second and first non-conductive adhesive members 92 and 91. Therefore, during the high-temperature and high-pressure bonding process, a film shape of the first non-conductive adhesive member 91 may be maintained, and flatness of the appearance of the display module 10 may be improved. In addition, by using a film having such a structure, the plurality of micro LEDs 50R, 50G, and 50B may not rotate or move, and may be precisely bonded to desired positions of the electrode pads 22a, 22b, 22c, 22d, 22e, and 22f.

Thereafter, the electrodes 51a, 51b, 51c, 51d, 51e, and 51f of the plurality of micro LEDs 50R, 50G, and 50B may be bonded to the electrode pads 22a, 22b, 22c, 22d, 22e, and 22f of the substrate 20. For example, the solder bumps and/or conductive particles included in the second non-conductive adhesive member 92 may be melted by heat to form a metal compound together with the electrodes 51a, 51b, 51c, 51d, 51e, and 51f of the plurality of micro LEDs 50R, 50G, and 50B and the electrode pads 22a, 22b, 22c, 22d, 22e, and 22f of the substrate 20.

Thereafter, by the heat applied to the substrate 20 and/or the plurality of non-conductive adhesive members 91 and 92, the first non-conductive adhesive member 91 may be cured at the first curing temperature, and the second non-conductive adhesive member 92 may be cured at the second curing temperature.

For example, while the electrodes 51a, 51b, 51c, 51d, 51e, and 51f of the plurality of micro LEDs 50R, 50G, and 50B are in contact with the electrode pads 22a, 22b, 22c, 22d, 22e, and 22f of the substrate 20 or the solder bumps formed on the electrode pads 22a, 22b, 22c, 22d, 22e, and 22f, the first non-conductive adhesive member 91 may be cured at a temperature higher than or equal to the first curing temperature.

For example, while the electrodes 51a, 51b, 51c, 51d, 51e, and 51f of the plurality of micro LEDs 50R, 50G, and 50B are in contact with the electrode pads 22a, 22b, 22c, 22d, 22e, and 22f of the substrate 20 or the solder bumps formed on the electrode pads 22a, 22b, 22c, 22d, 22e, and 22f, the second non-conductive adhesive member 92 may be cured at a temperature higher than or equal to the second curing temperature.

Accordingly, the plurality of micro LEDs 50R, 50G, and 50B may be securely fixed to the substrate 20 by the cured first non-conductive adhesive member 91 and the cured second non-conductive adhesive member 92, while being inserted into the first non-conductive adhesive member 91 and the second non-conductive adhesive member 92.

In addition, for the bonding process, the first non-conductive adhesive member 91 and the second non-conductive adhesive member 92, which have different curing temperatures, viscosities, and glass transition temperatures, may be laminated, thereby preventing the first and/or second non-conductive adhesive members 91 and 92 from being pre-cured during the bonding process, and the first non-conductive adhesive member 91 or the second non-conductive adhesive member 92 may be prevented from being cured while the electrodes 51a, 51b, 51c, 51d, 51e, and 51f of the plurality of light emitting elements 50R, 50G, and 50B are not bonded to the electrode pads 22a, 22b, 22c, 22d, 22e, and 22f of the substrate 20.

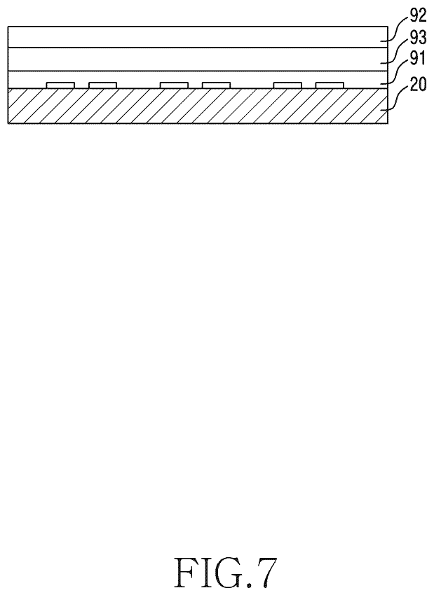

FIG. 7 illustrates an example of a substrate having three non-conductive adhesive members formed thereon, according to an embodiment of the disclosure.

Referring to FIG. 7, a first non-conductive adhesive member 91, a second non-conductive adhesive member 92, and a third non-conductive adhesive member 93 may be formed on a substrate 20 according to an embodiment. The third non-conductive adhesive member 93 may be formed between the first non-conductive adhesive member 91 and the second non-conductive adhesive member 92.

According to an embodiment, the first non-conductive adhesive member 91, the second non-conductive adhesive member 92, and the third non-conductive adhesive member 93 may be non-conductive films. The first non-conductive adhesive member 91 may be formed on the substrate 20 through a lamination process. The third non-conductive adhesive member 93 may be formed on the first non-conductive adhesive member 91 through the lamination process. The second non-conductive adhesive member 92 may be formed on the third conductive adhesive member 93 through the lamination process.

According to an embodiment, the first non-conductive adhesive member 91 may be formed of a material which is cured at a first curing temperature or higher. The second non-conductive adhesive member 92 may be formed of a material which is cured at a second curing temperature or higher. The third non-conductive adhesive member 93 may be formed of a material which is cured at a third curing temperature or higher. The second curing temperature may be higher than the first curing temperature and the third curing temperature. For example, the first non-conductive adhesive member 91, the second non-conductive adhesive member 92, and the third non-conductive adhesive member 93 may have different curing temperatures, viscosities, and glass transition temperatures (Tg) by varying types and contents of components of the first, second, and third non-conductive adhesive members 91, 92, and 93. For example, the first non-conductive adhesive member 91, the second non-conductive adhesive member 92, and the third non-conductive adhesive member 93 may have different curing temperatures, viscosities, and glass transition temperatures (Tg) by including different types and contents of at least one of additives, curing agents, fluxes, or epoxies.

According to an embodiment, the second non-conductive adhesive member 92 may be formed of a material having a higher viscosity than that of the first non-conductive adhesive member 91 and that of the third non-conductive adhesive member 93.

According to an embodiment, the first non-conductive adhesive member 91 and the third non-conductive adhesive member 93 may be transparent non-conductive films, but the disclosure is not limited thereto.

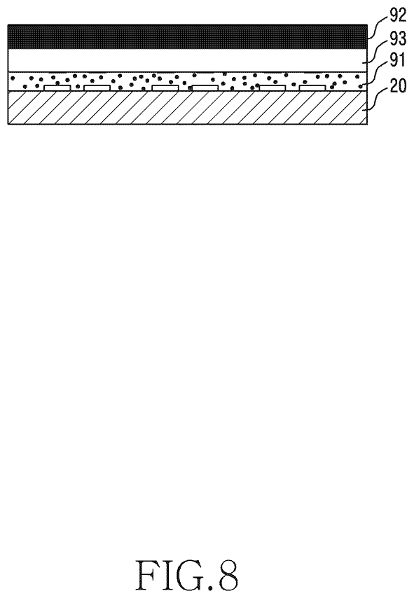

FIG. 8 illustrates an example of a substrate having three non-conductive adhesive member formed thereon, according to an embodiment of the disclosure.

Referring to FIG. 8, according to an embodiment, at least one of a first non-conductive adhesive member 91, a second non-conductive adhesive member 92, and a third non-conductive adhesive member 93 may have a black color. For example, among the first non-conductive adhesive member 91, the second non-conductive adhesive member 92, and the third non-conductive adhesive member 93, the second non-conductive adhesive member 92 forming an uppermost layer may have the black color.

According to an embodiment, at least one of the first non-conductive adhesive member 91, the second non-conductive adhesive member 92, and the third non-conductive adhesive member 93 may include a plurality of conductive particles. For example, among the first non-conductive adhesive member 91, the second non-conductive adhesive member 92, and the third non-conductive adhesive member 93, the first non-conductive adhesive member 91 forming the uppermost layer may include the plurality of conductive particles.

The plurality of conductive particles may be conductive powders, and may include, for example, at least one conductive material selected from Sn, Cu, Ni, In, Ag, Au, Carbon, Co, Fe, Cr, and Mo. A density of the plurality of conductive particles in the first non-conductive adhesive member 91 may be less than or equal to a predetermined value. Accordingly, the first non-conductive adhesive member 91 may maintain electrically non-conductive properties.

Although it is described in FIGS. 7 and 8 that the three non-conductive adhesive members 91, 92, and 93 are formed on the substrate 20, the disclosure is not limited thereto. In addition, although it is described in FIG. 8 that the first non-conductive adhesive member 91 includes the plurality of conductive particles when the second non-conductive adhesive member 92 has the black color, the disclosure is not limited thereto.

For example, four or more non-conductive adhesive members may be formed on the substrate 20. In this case, at least one of the non-conductive adhesive members may have the black color, and at least one of the non-conductive adhesive members may include the conductive particles. Preferably, among the non-conductive adhesive members, a non-conductive adhesive member forming an uppermost layer may have the black color, and the remaining non-conductive adhesive members may have a transparent color. Preferably, a non-conductive adhesive member forming a lowermost layer may include the conductive particles. Additionally, preferably, among the non-conductive adhesive members, the non-conductive adhesive member forming the uppermost layer may have a highest curing temperature and a highest viscosity, and curing temperatures and viscosities of the remaining non-conductive adhesive members may be set differently according to a bonding process.

An embodiment of the disclosure may provide a display module including: a substrate including a plurality of electrode pads; a first non-conductive adhesive member formed on a surface of the substrate and having a first curing temperature; a second non-conductive adhesive member formed on the first non-conductive adhesive member and having a second curing temperature; and a plurality of light emitting elements bonded to the plurality of electrode pads. Electrodes of the plurality of light emitting elements sequentially may be respectively bonded to the plurality of electrode pads by sequentially passing through the second non-conductive adhesive member and the first non-conductive adhesive member. The second curing temperature may be higher than the first curing temperature.

In addition, the first non-conductive adhesive member and the second non-conductive adhesive member may be formed on the surface of the substrate as a plurality of layers.

In addition, the first non-conductive adhesive member may have a first viscosity. The second non-conductive adhesive member may have a second viscosity. The second viscosity may be higher than the first viscosity.

In addition, the second non-conductive adhesive member may be a black non-conductive film.

In addition, the first non-conductive adhesive member may be a non-conductive film including conductive particles.

In addition, the display module may further include a third non-conductive adhesive member formed between the first non-conductive adhesive member and the second non-conductive adhesive member.

In addition, a third curing temperature of the third non-conductive adhesive member may be lower than the second curing temperature of the second non-conductive adhesive member.

In addition, the electrodes of the plurality of light emitting elements may be respectively bonded to the plurality of electrode pads by sequentially passing through the second non-conductive adhesive member, the third non-conductive adhesive member, and the first non-conductive adhesive member.

In addition, a third viscosity of the third non-conductive adhesive member may be lower than the second viscosity of the second non-conductive adhesive member.

In addition, at least one of the second non-conductive adhesive member and the third non-conductive adhesive member may be a black non-conductive film. The first non-conductive adhesive member may be a non-conductive film including conductive particles.

An embodiment of the disclosure may provide a method of bonding a plurality of light emitting elements on a substrate of a display module. The method may include: forming a first non-conductive adhesive member having a first curing temperature on a substrate including a plurality of electrode pads; forming a second non-conductive adhesive member having a second curing temperature on the first non-conductive adhesive member; aligning a plurality of electrodes of the light emitting elements on the plurality of electrode pads; applying heat and pressure to the plurality of electrodes of the light emitting elements such that the plurality of electrodes of the light emitting elements pass through the second non-conductive adhesive member within a first temperature range; applying the heat and the pressure to the plurality of electrodes of the light emitting elements such that the plurality of electrodes of the light emitting elements are inserted into the first non-conductive adhesive member within a second temperature range and are brought into contact with the plurality of electrode pads; and applying the heat and the pressure to the plurality of electrodes of the light emitting element after the plurality of electrodes of the light emitting element have passed through the second non-conductive adhesive member, such that the plurality of electrodes of the light emitting element are bonded to the plurality of electrode pads within the second non-conductive adhesive member. The second curing temperature may be higher than the first curing temperature.

In addition, a second viscosity of the second non-conductive adhesive member may be higher than a first viscosity of the first non-conductive adhesive member.

In addition, the forming of the first non-conductive adhesive member may include attaching a first non-conductive film having a first curing temperature on the substrate through a lamination process. The forming of the second non-conductive adhesive member may include attaching a second non-conductive film having a second curing temperature on the first non-conductive film through the lamination process.

In addition, the heat and the pressure may be applied to the plurality of electrodes of the light emitting elements, such that the plurality of electrodes of the light emitting elements pass through the second non-conductive adhesive member within a first temperature range lower than the first curing temperature and the second curing temperature.

In addition, the heat and the pressure may be applied to the plurality of electrodes of the light emitting elements, such that the plurality of electrodes of the light emitting elements are brought into contact with the plurality of electrode pads in the first non-conductive adhesive member within a second temperature range lower than the first curing temperature and the second curing temperature.

In addition, the method may further include curing the first non-conductive adhesive member at a temperature higher than the first curing temperature, while the plurality of electrodes of the light emitting elements are in contact with the plurality of electrode pads.

In addition, the method may further include curing the second non-conductive adhesive member at a temperature higher than the second curing temperature, while the plurality of electrodes of the light emitting elements are in contact with the plurality of electrode pads.

In addition, the second non-conductive adhesive member may be a black non-conductive film.

The first non-conductive adhesive member may be a non-conductive film including conductive particles.

In addition, the forming of the second non-conductive adhesive member having the second curing temperature on the first non-conductive adhesive member may include: forming a third non-conductive adhesive member having a third curing temperature on the first non-conductive adhesive member; and forming the second non-conductive adhesive member on the third non-conductive adhesive member.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program) including one or more instructions that are stored in a storage medium (e.g., internal memory or external memory) that is readable by a machine (e.g., the electronic device). For example, a processor (e.g., the processor) of the machine (e.g., the electronic device) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A display device comprising:
a substrate including a plurality of electrode pads;
a first non-conductive adhesive member formed on a surface of the substrate and having a first curing temperature;
a second non-conductive adhesive member formed on the first non-conductive adhesive member and having a second curing temperature; and
a plurality of light emitting elements bonded to the plurality of electrode pads,
wherein electrodes of the plurality of light emitting elements are respectively bonded to the plurality of electrode pads by sequentially passing through the second non-conductive adhesive member and the first non-conductive adhesive member, and
wherein the second curing temperature is higher than the first curing temperature.

2. The display device of claim 1, wherein the first non-conductive adhesive member and the second non-conductive adhesive member are formed on the surface of the substrate as a plurality of layers.

3. The display device of claim 1,
wherein the first non-conductive adhesive member has a first viscosity, and the second non-conductive adhesive member has a second viscosity, and
wherein the second viscosity is higher than the first viscosity.

4. The display device of claim 1, wherein the second non-conductive adhesive member is a black non-conductive film.

5. The display device of claim 1, wherein the first non-conductive adhesive member is a non-conductive film including conductive particles.

6. The display device of claim 1, further comprising a third non-conductive adhesive member formed between the first non-conductive adhesive member and the second non-conductive adhesive member.

7. The display device of claim 6, wherein a third curing temperature of the third non-conductive adhesive member is lower than the second curing temperature of the second non-conductive adhesive member.

8. The display device of claim 7, wherein the electrodes of the plurality of light emitting elements are respectively bonded to the plurality of electrode pads by sequentially passing through the second non-conductive adhesive member, the third non-conductive adhesive member, and the first non-conductive adhesive member.

9. The display device of claim 6,
wherein the first non-conductive adhesive member has a first viscosity, and the second non-conductive adhesive member has a second viscosity,
wherein the second viscosity is higher than the first viscosity, and
wherein a third viscosity of the third non-conductive adhesive member is lower than the second viscosity of the second non-conductive adhesive member.

10. The display device of claim 6,
wherein at least one of the second non-conductive adhesive member and the third non-conductive adhesive member is a black non-conductive film, and
wherein the first non-conductive adhesive member is a non-conductive film including conductive particles.

11. A method of bonding a plurality of light emitting elements on a substrate of a display device, the method comprising:
forming a first non-conductive adhesive member having a first curing temperature on a substrate including a plurality of electrode pads;
forming a second non-conductive adhesive member having a second curing temperature on the first non-conductive adhesive member;
aligning a plurality of electrodes of the light emitting elements on the plurality of electrode pads;
applying heat and pressure to the plurality of electrodes of the light emitting elements such that the plurality of electrodes of the light emitting elements pass through the second non-conductive adhesive member within a first temperature range;
applying the heat and the pressure to the plurality of electrodes of the light emitting elements such that the plurality of electrodes of the light emitting elements are inserted into the first non-conductive adhesive member within a second temperature range and are brought into contact with the plurality of electrode pads; and
applying the heat and the pressure to the plurality of electrodes of the light emitting elements after the plurality of electrodes of the light emitting elements have passed through the second non-conductive adhesive member, such that the plurality of electrodes of the light emitting elements are bonded to the plurality of electrode pads within the second non-conductive adhesive member,
wherein the second curing temperature is higher than the first curing temperature.

12. The method of claim 11, wherein a second viscosity of the second non-conductive adhesive member is higher than a first viscosity of the first non-conductive adhesive member.

13. The method of claim 11,
wherein the forming of the first non-conductive adhesive member comprises attaching a first non-conductive film having a first curing temperature on the substrate through a lamination process, and
wherein the forming of the second non-conductive adhesive member comprises attaching a second non-conductive film having a second curing temperature on the first non-conductive film through the lamination process.

14. The method of claim 11, wherein the heat and the pressure are applied to the plurality of electrodes of the light emitting elements, such that the plurality of electrodes of the light emitting elements pass through the second non-conductive adhesive member within a first temperature range lower than the first curing temperature and the second curing temperature.

15. The method of claim 11, wherein the heat and the pressure are applied to the plurality of electrodes of the light emitting elements, such that the plurality of electrodes of the light emitting elements are brought into contact with the plurality of electrode pads in the first non-conductive adhesive member within a second temperature range lower than the first curing temperature and the second curing temperature.

16. The method of claim 11, further comprising:
curing the first non-conductive adhesive member at a temperature higher than the first curing temperature, while the plurality of electrodes of the light emitting elements are in contact with the plurality of electrode pads.

17. The method of claim 11, further comprising:
curing the second non-conductive adhesive member at a temperature higher than the second curing temperature, while the plurality of electrodes of the light emitting elements are in contact with the plurality of electrode pads.

18. The method of claim 11, wherein the second non-conductive adhesive member is a black non-conductive film.

19. One or more non-transitory computer-readable storage media storing one or more computer programs including computer-executable instructions that, when executed by one or more processors of an electronic device individually or collectively, cause the electronic device to perform operations, the operations comprising:
forming a first non-conductive adhesive member having a first curing temperature on a substrate including a plurality of electrode pads;
forming a second non-conductive adhesive member having a second curing temperature on the first non-conductive adhesive member;
aligning a plurality of electrodes of light emitting elements on the plurality of electrode pads;
applying heat and pressure to the plurality of electrodes of the light emitting elements such that the plurality of electrodes of the light emitting elements pass through the second non-conductive adhesive member within a first temperature range;
applying the heat and the pressure to the plurality of electrodes of the light emitting elements such that the plurality of electrodes of the light emitting elements are inserted into the first non-conductive adhesive member within a second temperature range and are brought into contact with the plurality of electrode pads; and
applying the heat and the pressure to the plurality of electrodes of the light emitting elements after the plurality of electrodes of the light emitting elements have passed through the second non-conductive adhesive member, such that the plurality of electrodes of the light emitting elements are bonded to the plurality of electrode pads within the second non-conductive adhesive member,
wherein the second curing temperature is higher than the first curing temperature.

20. The one or more non-transitory computer-readable storage media of claim 19, wherein a second viscosity of the second non-conductive adhesive member is higher than a first viscosity of the first non-conductive adhesive member.
